(19) United States
(12) Patent Application Publication
(10) Pub. No.: US 2010/0203729 A1
(43) Pub. Date: Aug. 12, 2010

(54) COMPOSITION FOR CHEMICAL MECHANICAL POLISHING

(75) Inventors: Ji-sung LEE, Hwaseong-si (KR); Young-sam LIM, Bucheon-si (KR); Hyun-joon KIM, Seoul (KR); Yun-deok KANG, Bucheon-si (KR); Song-yi LEE, Seoul (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (JP)

(21) Appl. No.: 12/630,353

(22) Filed: Dec. 3, 2009

(30) Foreign Application Priority Data
Feb. 10, 2009 (KR) 10-2009-0010622

(51) Int. Cl. H01L 21/306; C09K 13/00

(52) U.S. Cl. 438/692; 252/79.1; 257/E21.23

(57) ABSTRACT

Provided is a composition for use in chemical mechanical polishing. The composition includes an amino acid and its derivatives, a surfactant, and an additive that increases the swelling of polishing particles.

### CROSS-REFERENCE TO RELATED APPLICATIONS

This application claims priority from Korean Patent Application No. 10-2009-0010622, filed on Feb. 10, 2009, in the Korean Intellectual Property Office, the disclosure of which is incorporated herein in its entirety by reference.

### BACKGROUND

The inventive concept relates to a composition adapted for chemical mechanical polishing used in a manufacturing process of a semiconductor device, and more particularly, to a polishing solution for chemical mechanical polishing using a polishing pad that includes polishing particles.

Chemical mechanical polishing (CMP) is widely used in planarizing layers or films formed on a semiconductor substrate. For example, CMP is used for planarizing an interlayer insulating layer, forming a shallow trench isolation (STI) film, or in a damascene process.

FIGS. 1A through 1D are cross-sectional views sequentially illustrating a CMP process of forming an STI of a semiconductor device. Referring to FIG. 1A, after sequentially forming a pad oxide film 12 and a mask nitride film 13 on a semiconductor substrate 11, an STI 14 is formed in the semiconductor substrate 11 using a photography etching process. Referring to FIG. 1B, an insulating film 15 is formed to fill the STI 14. Referring to FIG. 1C, using the mask nitride film 13 as a stoppage film, the semiconductor substrate 11 is planarized by polishing the insulating film 15 using a chemical mechanical polishing method to keep the insulating film 15 only on the STI 14. Referring to FIG. 1D, the mask nitride film 13 is removed by wet-etching.

In a CMP process of forming an STI film, an insulating film that fills the STI film is planarized by polishing. However, as shown in FIG. 2, concave surfaces may be formed when the insulating film is removed. This is referred to as dashing. Due to dashing, a step difference may occur, and thus, a photography etching process for forming a gate electrode may not be properly performed in a subsequent process, thereby reducing a device reliability.

In related-art chemical mechanical polishing, polishing is performed by supplying slurry that includes polishing or abrasive particles to a frictional surface between a polishing pad and a semiconductor substrate. In this case, however, dashing may easily occur since the slurry that contains the polishing particles is concentrated in a trench.

In order to reduce dashing, a fixed abrasive polishing where chemical mechanical polishing is performed using a fixed abrasive pad which contains polishing particles attached thereto has been introduced. However, such fixed abrasive polishing is disadvantageous in that the polishing speed is low and there is a high risk of causing defects and scratches.

### SUMMARY

The inventive concept provides a polishing solution or dispersion adapted for chemical mechanical polishing, whereby the polishing speed may be increased and the generation of scratches and defects may be decreased while preventing dashing.

According to an aspect of the inventive concept, there is provided a composition adapted for fixed abrasive polishing which uses a fixed polishing pad containing polishing particles attached thereto, the composition including an amino acid or its derivatives, a surfactant, and an additive that increases swelling of the polishing particles.

A composition for use in chemical mechanical polishing of a surface of a substrate, wherein the chemical mechanical polishing uses polishing particles to polish the surface, the composition including: an amino acid or its derivatives; a surfactant; an additive that increases swelling of the polishing particles; and a solvent.

The additive may adjust the viscosity of the composition.

The amino acid may include proline.

The amino acid may include lysine, arginine, N-methylglycine, glycine, or alanine.

The surfactant may include a nonionic-surfactant.

The nonionic-surfactant may include polyoxyethylene sorbitan monolaurate or polyethylene glycol octylphenol ether.

The additive may include polyethylene glycol. The polyethylene glycol may have a molecular weight of 10,000 to 35,000.

The composition of a solution may further include a pH control agent. The pH control agent may be KOH, tetramethylammonium hydroxide (TMAH), tetraethylammonium hydroxide (TEAH), or NH₄OH.

The composition of the solution may have pH in a range of 9 to 11.

The inventive concept further provides a method of polishing a substrate surface, which method includes disposing a substrate having a layer formed on at least one of its surfaces, in a chemical mechanical polishing apparatus; positioning the substrate in proximity with a fixed abrasive chemical-mechanical polishing pad; providing a polishing composition between the substrate and the polishing pad, wherein the polishing composition includes an amino acid or its derivatives, a surfactant, and an additive that promotes swelling of the polishing particles; and chemical-mechanical polishing the layer with the fixed abrasive polishing pad using the polishing composition received between the substrate and the abrasive polishing pad.

### BRIEF DESCRIPTION OF THE DRAWINGS

Exemplary embodiments of the inventive concept will be more clearly understood from the following detailed description taken in conjunction with the accompanying drawings in which:

FIGS. 1A through 1D are cross-sectional views sequentially illustrating a CMP process of forming an STI of a semiconductor device, according to exemplary embodiments;

FIG. 2 is a cross-sectional view of a shallow trench isolation film on which dashing is generated after performing a related-art chemical mechanical polishing process;

FIG. 3 is a graph showing the polishing speed of a silicon oxide film of comparative examples 1 through 5;

FIG. 4 is a graph showing the polishing speed of a silicon oxide film according to exemplary embodiments 1 through 5 of the inventive concept; and

FIG. 5 is a graph showing the polishing speed of a silicon oxide film of comparative example 6 and according to exemplary embodiments 6 through 8 of the inventive concept.

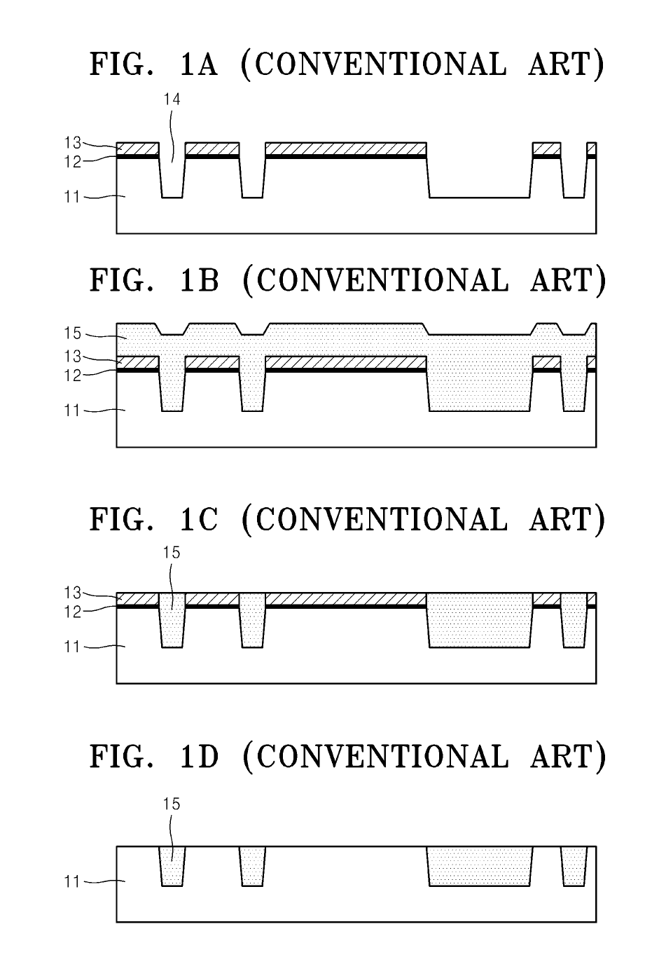

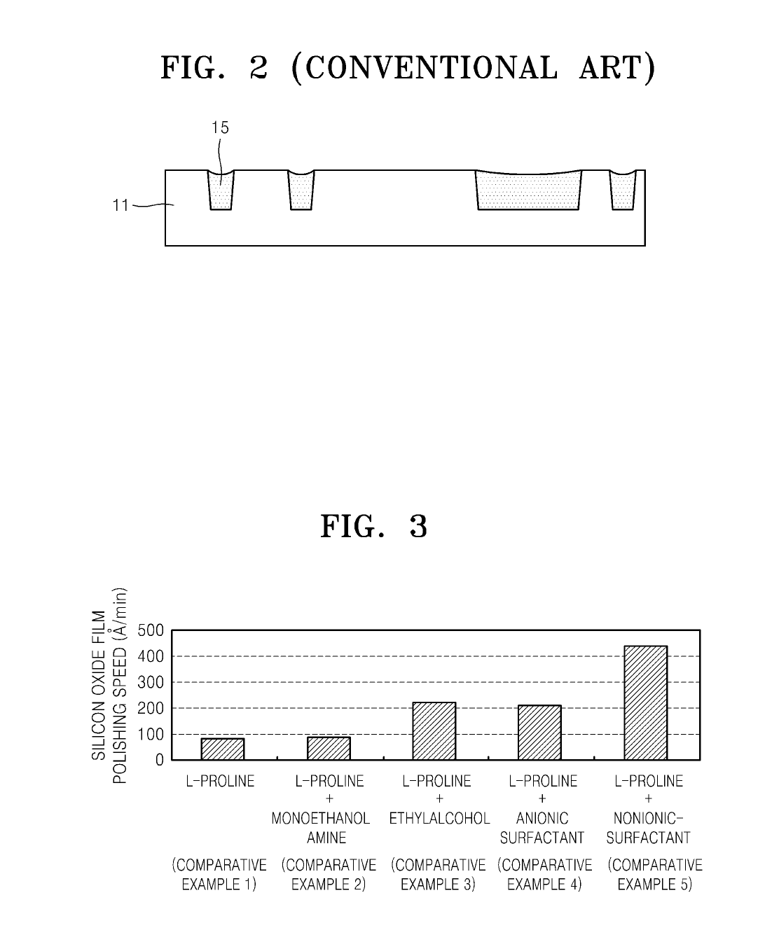

### DETAILED DESCRIPTION OF THE EMBODIMENTS

The present invention will be described more fully with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, lengths and sizes of layers and regions may be exaggerated for clarity. Like reference numerals in the drawings denote like elements.

The composition according to an embodiment of the inventive concept may be used in chemical mechanical polishing of a silicon oxide film. The composition may contain a solvent and present as a solution or dispersion. The composition according to an embodiment of the inventive concept may be used in fixed abrasive chemical mechanical polishing in which polishing particles are fixed to a polishing pad. Also, while the disclosure describes the composition mostly with respect to the fixed abrasive polishing, the composition according to an embodiment of the inventive concept may also be used for chemical mechanical polishing in which polishing particles are dispersed in slurry.

The composition of a polishing solution according to an embodiment of the inventive concept includes: a selectivity control agent for controlling the selectivity of a silicon nitride film to a silicon oxide film; a surfactant that increases a polishing speed through improving wettability of a polishing pad and a semiconductor substrate; and an additive that controls viscosity of the polishing solution and facilitates the discharge of polishing particles from a post by swelling, wherein the post is a structure of the polishing pad that contains the polishing particles.

The selectivity control agent may adjust the polishing activity in a way to polish a silicon oxide film to a greater degree than a silicon nitride film. The selectivity control agent decreases or stops at the silicon nitride film. In embodiments of the inventive concept, the selectivity control agent includes an amino acid and its derivatives. The amino acid may include lysine, arginine, proline, n-methylglycine, glycine, and alanine. The amino acid and its derivatives that include a carboxyl group (—COOH) may increase the polishing selectivity toward a silicon oxide film over a silicon nitride film by interrupting the polishing of the silicon nitride film by being attached onto the silicon nitride film.

The surfactant may decrease hydrophobic characteristics of the polishing pad, thereby increasing wettability of the polishing pad, and thus, may increase the polishing speed. The surfactant may be a non-ionic surfactant that includes polyoxyethylene sorbitan monolaurate or polyethylene glycol octylphenol ether.

The additive may control the viscosity of the polishing solution and increase polishing speed by promoting swelling of polishing particles in the post of the polishing pad. The polishing particles may include a ceria-based material. The additive may be polyethylene glycol (PEG) having a molecular weight of 1,000 to 35,000, and preferably, a molecular weight of 10,000 to 35,000.

The polishing solution proposed in the embodiments of the inventive concept may include the amino acid and its derivatives described above in an amount of 0.1 to 5 weight % based on the total weight of the composition. In another embodiment, the amount may be 1 to 4 weight %. Still in another embodiment, the amount may be 2 to 4 weight %.

The composition may include a non-ionic surfactant in an amount of 1 to 500 weight ppm based on the composition. The amount may be 5 to 200 weight ppm. In another embodiment, the amount may be 10 to 100 weight ppm. The polishing composition may also include the additive in an amount of 0.1 to 5 weight % based on the total weight of the composition. In another embodiment, the amount may be 0.1 to 2 weight %, and in still another embodiment, the amount may be 0.3 to 0.8 weight %. The composition may contain an aqueous solvent and be of a form of aqueous solution or dispersion. Examples of aqueous solvent include water, a mixture of water and an alcohol, or a mixture of water and an organic solvent which is miscible with water, and the like. Examples of the alcohol may include, but are not limited to, methanol, ethanol, 1-propanol, or 2-propanol. Examples of the organic solvent which is miscible with water may include, but are not limited to, acetone, or methyl ethyl ketone. The polishing solution may be manufactured by mixing the main components at room temperature.

The composition according to the embodiments of the inventive concept may be used in a pH range of 9 to 11. The composition may include a pH control agent. For example KOH, tetramethylammonium hydroxide (TMAH), tetraethylammonium hydroxide (TEAH), or NH₄OH can be used as a pH control agent. The composition may be used, but not limited to, in an orbital type polishing or a rotary type polishing.

The use of the composition as a polishing solution may increase the polishing speed and reduce polishing pressure. Accordingly, defects and scratches that may occur during chemical mechanical polishing may be reduced.

According to another aspect of the inventive concept, there is provided a method of polishing a substrate surface, which method includes disposing a substrate having a layer formed on at least one of its surfaces, in a chemical mechanical polishing apparatus; positioning the substrate in proximity with a fixed abrasive chemical-mechanical polishing pad; providing the above-described polishing composition between the substrate and the polishing pad; and chemical-mechanical polishing the layer with the fixed abrasive polishing pad using the polishing composition received between the substrate and the abrasive polishing pad.

A polishing solution according to embodiments of the inventive concept will now be described along with comparative examples. In the following comparative examples and embodiments, an orbital type UNIPLA210 (a product of Dusan) as a polishing apparatus and SWR542 (a product of 3M) as a polishing pad were used. The polishing solutions of the comparative examples and the embodiments were maintained at pH of 10.5 during the chemical mechanical polishing.

### Comparative Examples 1 Through 5

Monoethanol amine, ethylalcohol, an anionic surfactant, an nonionic-surfactant are selectively added to an aqueous solution that contains 2.5 weight % L-proline, and afterwards, polishing speeds of chemical mechanical polishing with respect to a silicon oxide film and a silicon nitride film were evaluated using the aqueous solution.

Table 1 summarizes the evaluation results of comparative examples 1 through 5. FIG. 3 shows the polishing speeds of the silicon oxide film according to the comparative examples 1 through 5.

TABLE 1

| | | | | | | Polishing | Polishing |
|---|---|---|---|---|---|---|---|
| | | Monoethanol | | Anionic | Nonionic- | speed of | speed of |
| | L-proline | amine | Ethylalcohol | surfactant | surfactant | silicon oxide | silicon nitride |
| Item | (weight %) | (weight %) | (weight %) | (weight %) | (weight %) | film (Å/min) | film (Å/min) |
| Comparative | 2.5 | | | | | 83 | 8 |
| example 1 | | | | | | | |
| Comparative | 2.5 | 0.1 | | | | 90 | 11 |
| example 2 | | | | | | | |
| Comparative | 2.5 | | 10 | | | 220 | 6 |
| example 3 | | | | | | | |
| Comparative | 2.5 | | | 0.001 | | 210 | 12 |
| example 4 | | | | | | | |
| Comparative | 2.5 | | | | 0.001 | 440 | 7 |
| example 5 | | | | | | | |

The result of polishing speed of comparative example 1 was obtained when the aqueous solution that contains 2.5 weight % L-proline was used.

The result of polishing speed of comparative example 2 was obtained when the aqueous solution that contains 2.5 weight % L-proline and 0.1 weight % monoethanol amine was used.

The result of polishing speed of comparative example 3 was obtained when the aqueous solution that contains 2.5 weight % L-proline and 10 weight % ethylalcohol was used.

The result of polishing speed of comparative example 4 was obtained when the aqueous solution that contains 2.5 weight % L-proline and 0.001 weight % anionic surfactant was used. The anionic surfactant was a polyethylene glycol octylphenol ether group material.

The result of polishing speed of comparative example 5 was obtained when the aqueous solution that contains 2.5 weight % L-proline and 0.001 weight % nonionic-surfactant was used. The nonionic-surfactant was polyoxyethylene sorbitan monolaurate.

Referring to Table 1 and FIG. 3, in the comparative examples 1 through 5, when 0.1 weight % monoethanol amine is added to the aqueous solution that contains 2.5 weight % L-proline, the polishing speed of the silicon oxide film was not greatly increased when compared to the comparative example 1. When 10 weight % ethylalcohol or 0.001 weight % anionic surfactant was added to the aqueous solution that contains 2.5 weight % L-proline, the polishing speed of the silicon oxide film was increased more than twice when compared to the comparative example 1. When 0.001 weight % nonionic-surfactant was added to the aqueous solution that contains 2.5 weight % L-proline, the polishing speed of the silicon oxide film was increased more than four times when compared to the comparative example 1. In comparative examples 1 through 5, the polishing speed of the silicon nitride film was not greatly increased in none of the cases, and in the case of the comparative example 5 at which the polishing speed of the silicon oxide film was the greatest, the polishing selectivity (or preference) of the silicon oxide film over the silicon nitride film was the greatest.

### Embodiments 1 Through 5

In embodiments 1 through 5, the polishing speed of chemical mechanical polishing with respect to the silicon oxide film and the silicon nitride film according to the concentration of nonionic-surfactant in an aqueous solution that contains 2.5 weight % L-proline were evaluated. The embodiment 1 employs the same condition as the comparative example 5.

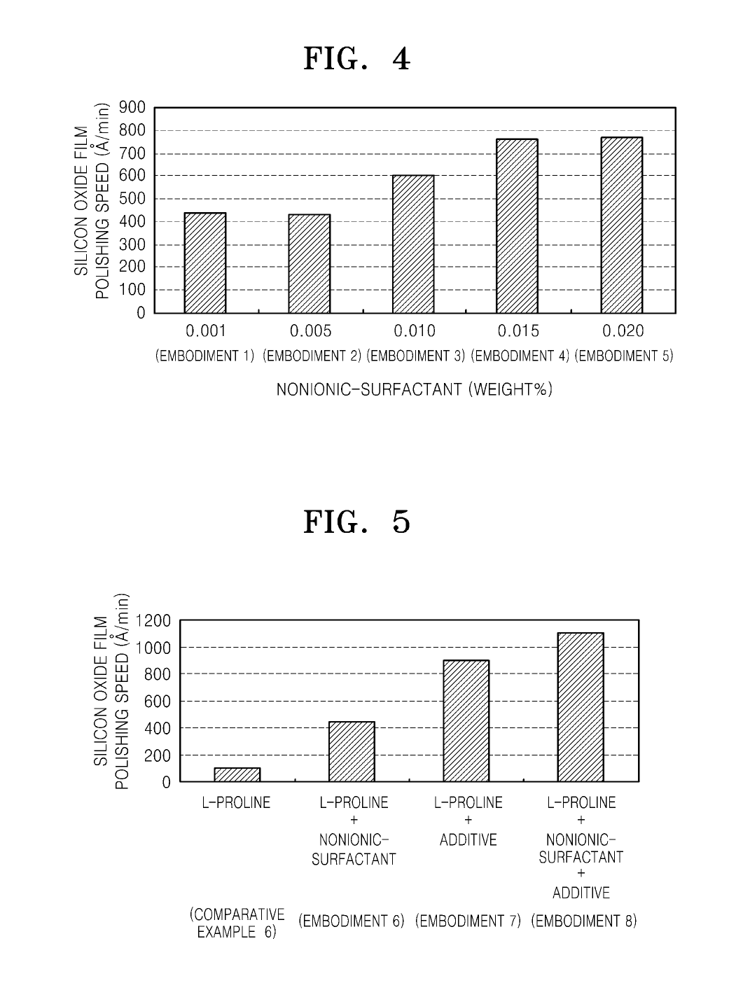

Table 2 summarizes the evaluation results of the polishing speeds of the silicon oxide film and the silicon nitride film according to the embodiments 1 through 5. FIG. 4 shows the polishing speeds of the silicon oxide film according to the exemplary embodiments 1 through 5.

TABLE 2

| | L- | | Polishing | Polishing |
|---|---|---|---|---|
| | proline | Nonionic- | speed of | speed of |
| | (weight | surfactant | silicon oxide | silicon nitride |
| Item | %) | (weight %) | film (Å/min) | film (Å/min) |
| Embodiment 1 | 2.5 | 0.001 | 440 | 7 |
| Embodiment 2 | 2.5 | 0.005 | 429 | 15 |
| Embodiment 3 | 2.5 | 0.010 | 604 | 11 |
| Embodiment 4 | 2.5 | 0.015 | 758 | 13 |
| Embodiment 5 | 2.5 | 0.020 | 767 | 13 |

The result of polishing speed of embodiment 1 was obtained when the aqueous solution that contains 2.5 weight % L-proline and 0.001 weight % nonionic-surfactant was used.

The result of polishing speed of embodiment 2 was obtained when the aqueous solution that contains 2.5 weight % L-proline and 0.005 weight % nonionic-surfactant was used.

The result of polishing speed of embodiment 3 was obtained when the aqueous solution that contains 2.5 weight % L-proline and 0.010 weight % nonionic-surfactant was used.

The result of polishing speed of embodiment 4 was obtained when the aqueous solution that contains 2.5 weight % L-proline and 0.015 weight % nonionic-surfactant was used.

The result of polishing speed of embodiment 5 was obtained when the aqueous solution that contains 2.5 weight % L-proline and 0.020 weight % nonionic-surfactant was used.

Referring to Table 2 and FIG. 4, in the embodiments 1 through 5, as the concentration of the nonionic-surfactant increases, it is seen that the polishing speed of the silicon oxide film also increases to a certain degree. However, the polishing speed of the silicon nitride film does not increase although the concentration of the nonionic-surfactant increases. Thus, when the polishing speed of the silicon oxide film increases, the selectivity of the silicon oxide film over the silicon nitride film also increases.

From the comparative examples 1 through 5, it is seen that the increment of the polishing speed of the silicon oxide film is increased when the an amine such as monoethanol amine, alcohol such as ethylalcohol, and a nonionic-surfactant instead of an anionic surfactant are added to the aqueous solution that contains 2.5 weight % L-proline.

From the embodiments 1 through 5, it is seen that the polishing speed of the silicon oxide film increases to a certain degree with the increase in the concentration of the nonionic-surfactant in the aqueous solution that contains 2.5 weight % L-proline.

### Embodiments 6 Through 8

The polishing speed of chemical mechanical polishing with respect to the silicon oxide film and the silicon nitride film according to the concentration of polyethylene glycol in an aqueous solution that contains 2.5 weight % L-proline were evaluated. Polyethylene glycol controls the viscosity of the polishing solution and promotes swelling of a post of a polishing pad.

Table 3 summarizes the evaluation results of the polishing speed according to the embodiments 6 through 8. FIG. 5 is a graph showing the polishing speed of the silicon oxide film according to the comparative example 6 and the exemplary embodiments 6 through 8.

TABLE 3

| | L- | | Polishing | Polishing |
|---|---|---|---|---|
| | proline | Polyethylene | speed of | speed of |
| | (weight | glycol | silicon oxide | silicon nitride |
| Item | %) | (weight %) | film (Å/min) | film (Å/min) |
| Comparative | 2.5 | — | 104 | 7 |
| example 6 | | | | |
| Embodiment 6 | 2.5 | 0.1 | 545 | 6 |
| Embodiment 7 | 2.5 | 0.3 | 908 | 13 |
| Embodiment 8 | 2.5 | 0.5 | 901 | 12 |

The result of polishing speed of comparative example 6 was obtained when the aqueous solution that contains 2.5 weight % L-proline was used as the comparative example 1

The result of polishing speed of embodiment 6 was obtained when the aqueous solution that contains 2.5 weight % L-proline and 0.1 weight % polyethylene glycol was used.

The result of polishing speed of embodiment 7 was obtained when the aqueous solution that contains 2.5 weight % L-proline and 0.3 weight % polyethylene glycol was used.

The result of polishing speed of embodiment 8 was obtained when the aqueous solution that contains 2.5 weight % L-proline and 0.5 weight % polyethylene glycol was used.

From the embodiments 6 through 8, it is seen that the polishing speed of the silicon oxide film was increased more than five times compared to the results of comparative example 6, and when the concentration of polyethylene glycol increased, the polishing speed of the silicon oxide film also increased to some degree.

### Embodiments 9 Through 11

The polishing speeds of chemical mechanical polishing with respect to the silicon oxide film and the silicon nitride film by adding both nonionic-surfactant and polyethylene glycol to an aqueous solution that contains 2.5 weight % L-proline were evaluated.

Table 4 summarizes the evaluation results of the embodiments 9 through 11. FIG. 5 shows the polishing speeds of the silicon oxide film: when only the aqueous solution that contains 2.5 weight % L-proline was used; when the nonionic-surfactant was added to the aqueous solution that contains 2.5 weight % L-proline; when the additive was added to the aqueous solution that contains 2.5 weight % L-proline; and when both the nonionic-surfactant and the additive were added to the aqueous solution that contains 2.5 weight % L-proline.

TABLE 4

| | | | | Polishing | Polishing |
|---|---|---|---|---|---|
| | | Nonionic- | Polyethylene | speed of | speed of |
| | L-proline | surfactant | glycol | silicon oxide | silicon nitride |
| Items | (weight %) | (weight %) | (weight %) | film (Å/min) | film (Å/min) |
| Embodiment 9 | 2.5 | 0.015 | 0.0 | 966 | 7 |
| Embodiment 10 | 2.5 | 0.001 | 0.5 | 1106 | 13 |
| Embodiment 11 | 2.5 | 0.015 | 0.5 | 1139 | 4 |

The result of polishing speed of comparative example 9 was obtained when the aqueous solution that contains 2.5 weight % L-proline and 0.015 weight % nonionic-surfactant was used.

The result of polishing speed of comparative example 10 was obtained when the aqueous solution that contains 2.5 weight % L-proline, 0.001 weight % nonionic-surfactant, and 0.05 weight % polyethylene glycol was used.

The result of polishing speed of comparative example 11 was obtained when the aqueous solution that contains 2.5 weight % L-proline, 0.015 weight % nonionic-surfactant, and 0.05 weight % polyethylene glycol was used.

Referring to Table 4 and FIG. 5, it is seen from the embodiments 9 through 11 that the polishing speed of the silicon oxide film was further increased when both the nonionic-surfactant and the polyethylene glycol are added to the aqueous solution that contains 2.5 weight % L-proline when compared to the case when only the nonionic-surfactant was added to the aqueous solution that contains 2.5 weight % L-proline. Also, from the embodiments 8, 10, and 11, the polishing speed of the silicon oxide film was further increased when both the nonionic-surfactant and polyethylene glycol were added to the aqueous solution that contains 2.5 weight % L-proline, compared to the case when only polyethylene glycol was added to the aqueous solution that contains 2.5 weight % L-proline.

The polishing compositions according to the embodiments of the inventive concept may increase the polishing speed, and accordingly, the pressure of a polishing process may be reduced, thereby reducing defects and scratches on a semiconductor substrate. Thus, the reliability of a semiconductor device may be increased.

The polishing compositions according to the embodiments of the inventive concept may be used not only in web type polishers but also in orbital type polishers.

While the above embodiments describe the use of the polishing compositions according to the embodiments of the inventive concept in fixed abrasive polishing, the polishing composition may also be used for chemical mechanical polishing in which polishing particles are dispersed in a slurry.

In chemical mechanical polishing using a fixed polishing pad, the use of the polishing solution according to an embodiment of the inventive concept may improve wettability between a polishing pad and a semiconductor substrate, may control viscosity of the polishing solution, and may facilitate the discharge of polishing particles from a post of a polishing pad. Therefore, productivity may be increased by increasing the polishing speed of a silicon oxide film, and defects and scratches of the semiconductor substrate may be reduced since the polishing process may be performed with a low pressure.

While the inventive concept has been particularly shown and described with reference to exemplary embodiments thereof, it will be understood that various changes in form and details may be made therein without departing from the spirit and scope of the following claims.

What is claimed is:

1. A composition for use in chemical mechanical polishing of a surface of a substrate, wherein the chemical mechanical polishing uses polishing particles to polish the surface, the composition comprising:
an amino acid or its derivatives;
a surfactant;
an additive that increases swelling of the polishing particles; and
a solvent.

2. The composition of claim 1, wherein the additive adjusts the viscosity of the polishing solution.

3. The composition of claim 1, wherein the amino acid comprises proline.

4. The composition of claim 1, wherein the amino acid comprises lysine, arginine, N-methylglycine, glycine, or alanine.

5. The composition of claim 1, wherein the surfactant comprises a nonionic-surfactant.

6. The composition of claim 5, wherein the nonionic-surfactant comprises polyoxyethylene sorbitan monolaurate or polyethylene glycol octylphenol ether.

7. The composition of claim 1, wherein the additive comprises polyethylene glycol.

8. The composition of claim 7, wherein the polyethylene glycol has a molecular weight of 1,000 to 35,000.

9. The composition of claim 1, which further comprises a pH adjusting agent.

10. The composition of claim 9, wherein the pH adjusting agent is KOH, tetramethylammonium hydroxide (TMAH), tetraethylammonium hydroxide (TEAH), or NH₄OH.

11. The composition of claim 9, which has the pH in a range of 9 to 11.

12. The composition of claim 1, wherein the chemical mechanical polishing is a fixed abrasive chemical mechanical polishing.

13. The composition of claim 1, wherein the surface of the substrate has a silicon oxide layer.

14. The composition of claim 1, which shows a greater polishing rate on a silicon oxide layer than that on a silicon nitride layer.

15. A method of polishing a surface of a substrate, comprising
disposing the substrate having a layer formed on its surface, in a chemical mechanical polishing apparatus, wherein the layer comprises at least a silicon oxide layer;
positioning the substrate in proximity with a fixed abrasive chemical-mechanical polishing pad;
providing a polishing composition between the substrate and the polishing pad, wherein the polishing composition includes an amino acid or its derivatives, a surfactant, polyethylene glycol, and a solvent; and
chemical-mechanical polishing the layer with the fixed abrasive polishing pad using the polishing composition received between the substrate and the abrasive polishing pad.
